(19) United States
(12) Patent Application Publication
(10) Pub. No.: US 2005/0105037 A1
(43) Pub. Date: May 19, 2005

(54) Flat panel display and method for fabricating the same

(76) Inventors: Hoon Kim, Seoul (KR); Ki-Yong Lee, Yongin-si (KR); Jin-Wook Seo, Suwon-si (KR)

Correspondence Address: MCGUIREWOODS, LLP, 1750 TYSONS BLVD, SUITE 1800, MCLEAN, VA, 22102, US

(21) Appl. No.: 10/959,977

(22) Filed: Oct. 8, 2004

(30) Foreign Application Priority Data
Nov. 17, 2003 (KR) 2003-81257

(51) Int. Cl. G02F 1/1345

(52) U.S. Cl. 349/151

(57) ABSTRACT

A flat panel display and method for fabricating the same are disclosed. In the flat panel display a substrate includes a pixel region having a plurality of unit pixels, and a peripheral circuit region arranged in the periphery of the pixel region. The peripheral circuit region also includes a driving circuit for driving the plurality of unit pixels. At least one circuit thin film transistor is positioned in the peripheral circuit region and includes a first semiconductor layer crystallized by a sequential lateral solidification method. At least one pixel thin film transistor is positioned in the pixel region and includes a second semiconductor layer having a channel region crystallized by one of a metal induced crystallization method or a metal induced lateral crystallization method.

### CROSS-REFERENCE TO RELATED APPLICATION

This application claims priority of Korean Patent Application No. 2003-81257, filed Nov. 17, 2003, the disclosure of which is herein incorporated by reference.

### BACKGROUND OF THE INVENTION

1. Field of the Invention

The present invention relates to flat panel displays generally and, more particularly, to a flat panel display having a thin film transistor and method for fabricating the same.

2. Description of the Related Art

In recent years, flat panel displays such as a liquid crystal display (LCD) or an organic light-emitting display device (OLED) have been active matrix types that produce high quality images. In theactive matrix display, a pixel electrode and a thin film transistor, for controlling electrical signals that are applied to the pixel electrode, are positioned in each unit pixel of a pixel region.

The thin film transistor includes a semiconductor layer, a gate insulating layer, and a gate electrode, and the semiconductor layer is generally a polysilicon layer which has electron mobility approximately 100 times higher than that of an amorphous silicon layer. Such high electron mobility of the polysilicon layer allows the forming of a driving circuit (for driving the unit pixels) near the pixel region.

The polysilicon layer is generally created by forming the amorphous silicon layer on a substrate and crystallizing the same. Often the polysilicon layers of pixel region and the driving circuit region are crystallized by the same crystallization method. This crystallization method includes solid phase crystallization (SPC), an excimer laser annealing (ELA), a sequential lateral solidification (SLS), a metal induced crystallization (MIC), a metal induced lateral crystallization (MILC), or the like. Each of the various crystallization methods produces crystals of different size and uniformity. The crystal size and the uniformity of the polycrystalline silicon play a significant role in the electrical properties of the thin film transistor.

As mentioned above, each unit pixel includes a TFT. Additionally, the driving circuit also includes a TFT. However, pixel TFTs differ from driving circuit TFTs in that they require different operational characteristics. Thus, when thin film transistors of the unit pixel and the driving circuit are formed by the same crystallization method as mentioned above, the operational characteristics of the thin film transistor of the unit pixel and the driving circuit are not readily adjusted so as to be different from each other. A solution is needed that optimizes the characteristics of TFTs for different uses.

### SUMMARY OF THE INVENTION

The present invention provides a flat panel display TFTs in a pixel region that have characteristics optimized for use in the pixel region, and TFTs in a peripheral circuit region that have characteristics optimized for use in the circuit region, and methods of manufacturing each.

An embodiment of the present invention provides a flat panel display. The flat panel display includes a pixel region having a plurality of unit pixels, and a peripheral circuit region arranged in a periphery of the pixel region and having a driving circuit for driving the plurality of unit pixels. At least one circuit thin film transistor is positioned in the peripheral circuit region and includes a first semiconductor layer crystallized by SLS. At least one pixel thin film transistor is positioned in the pixel region and includes a second semiconductor layer having a channel region crystallized by MIC or MILC.

The second semiconductor layer may have a channel region crystallized by the MILC. Further, the second semiconductor layer preferably has a region that is spaced apart from the channel region and crystallized by the MIC. The circuit thin film transistor further includes a first gate electrode positioned on the first semiconductor layer; and a first source/drain electrode that is spaced from the first gate electrode and in contact with the first semiconductor layer, wherein a metal silicide is preferably formed in a region in contact with the first source/drain electrode in the first semiconductor layer. And also, the pixel thin film transistor further includes a second gate electrode positioned on the second semiconductor layer, and a second source/drain electrode that is spaced apart from the second gate electrode and in contact with the second semiconductor layer, wherein a region below the second source/drain electrode is preferably crystallized by the MIC in the second semiconductor layer.

The flat panel display may be a liquid crystal display or organic light emitting display.

Another aspect of the present invention provides a method for fabricating a flat panel display. This method comprises the steps of preparing a substrate including a pixel region and a peripheral circuit region arranged in a periphery of the pixel region. An amorphous silicon layer is deposited on the substrate. The amorphous silicon layer of the peripheral circuit region is selectively crystallized by means of SLS to form a polycrystalline silicon layer. The amorphous silicon layer of the pixel region is selectively crystallized by means of MILC or MIC.

Selectively crystallizing the amorphous silicon layer of the pixel region may further include simultaneously patterning the polycrystalline silicon layer of the peripheral circuit region and the amorphous silicon layer of the pixel region to form a first semiconductor layer in the peripheral circuit region and a second semiconductor layer in the pixel region. This process may further include selectively crystallizing the second semiconductor layer of the pixel region by means of MILC. In this case, a metal silicide may be concurrently formed in the first semiconductor layer of the peripheral circuit region while the second semiconductor layer of the pixel region is selectively crystallized by the MILC.

Selectively crystallizing the second semiconductor layer of the pixel region by means of the MILC while forming the metal silicide in the first semiconductor layer of the peripheral circuit region, may further include forming a first gate electrode and on the first semiconductor layer of the peripheral circuit region and a second gate electrode on the second semiconductor layer of the pixel region, respectively; forming an interlayer on the gate electrodes and the semiconductor layers; forming a first source/drain contact hole for exposing a portion of the first semiconductor layer and a second source/drain contact hole for exposing a portion of the second semiconductor layer within the interlayer; depositing a crystallization inducing metal layer on the semiconductor layers exposed within the source/drain contact holes; and performing thermal treatment on the substrate where the crystallization inducing metal layer is deposited.

Selectively crystallizing the amorphous silicon layer of the pixel region by means of the MIC may further include forming a photoresist pattern for covering the polycrystalline silicon layer of the peripheral circuit region and for exposing the amorphous silicon layer of the pixel region; forming a crystallization inducing metal layer on the exposed amorphous silicon layer; and performing thermal treatment on the substrate where the crystallization inducing metal layer is formed.

The method of forming the crystallization inducing metal layer may be performed using at least one metal selected from a group consisting of Ni, Pd, Ti, Ag, Au, Al, Sn, Sb, Cu, Co, Cr, Mo, Tr, Ru, Rh, and Cd. More particularly, the method of forming the crystallization inducing metal layer may be performed using the Ni.

### BRIEF DESCRIPTION OF THE DRAWINGS

The above and other features and advantages of the present invention will become more apparent to those of ordinary skill in the art by describing in detail preferred embodiments thereof with reference to the attached drawings.

FIG. 1 is a plan view for showing a flat panel display in accordance with an embodiment of the present invention.

FIGS. 2A, 2B, 2C and 2D are cross-sectional views for illustrating a method for fabricating a flat panel display in accordance with a first embodiment of the present invention.

FIGS. 3A, 3B, 3C and 3D are cross-sectional views for illustrating a method for fabricating a flat panel display in accordance with a second embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, when a layer is described to be formed on another layer or on a substrate, it means that the layer may be formed on the other layer or on the substrate, or that a third layer may be interposed between the layer and the other layer or the substrate. Like numbers refer to like elements throughout the specification.

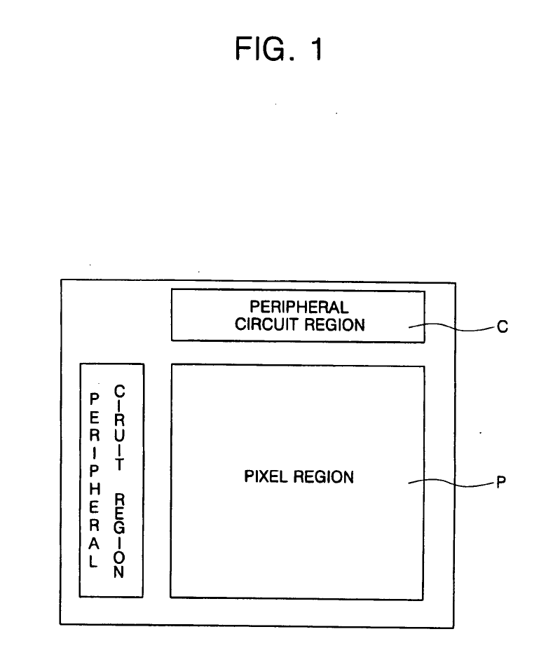

FIG. 1 is a plan view that illustrates a flat panel display in accordance with an embodiment of the present invention.

Referring to FIG. 1, a pixel region P having a plurality of unit pixels is positioned on the substrate 100. Peripheral circuit regions C having a driving circuit for driving the plurality of unit pixels are arranged at the periphery of the pixel region P. The plurality of unit pixels positioned in the pixel region P is arranged in a matrix form. Each unit pixel has a pixel electrode and a pixel thin film transistor for controlling data signals applied to the pixel electrode. The peripheral circuit region has a circuit thin film transistor that forms the driving circuit. The circuit thin film transistor has a first semiconductor layer crystallized by a SLS method, and the pixel thin film transistor has a second semiconductor layer having a channel region crystallized by any one of a MIC method and a MILC method. Thus, the pixel thin film transistor and the circuit thin film transistor are formed to have characteristics different from each other. Specifically, the circuit thin film transistor has high electron mobility, but the pixel thin film transistor has uniform electrical characteristics over the whole pixel region instead of high the electron mobility.

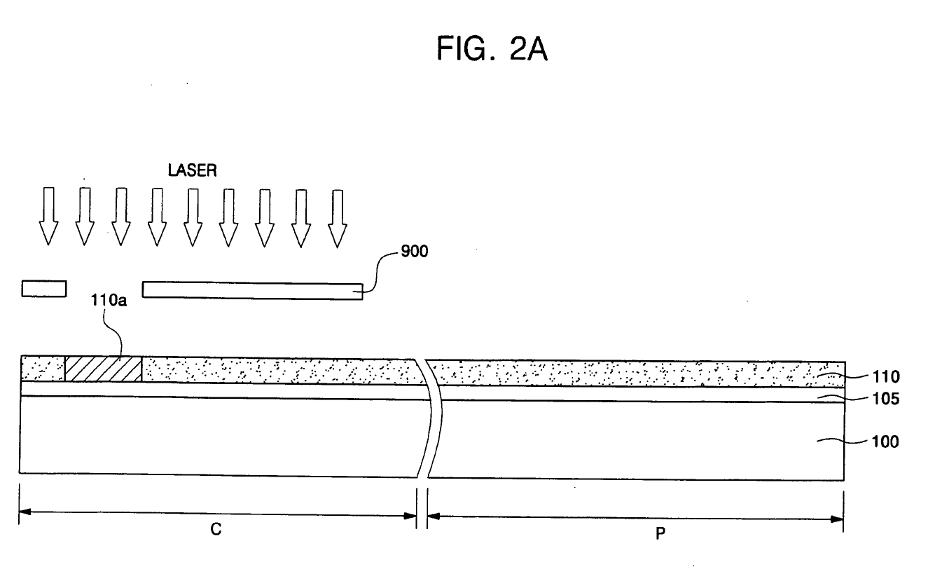

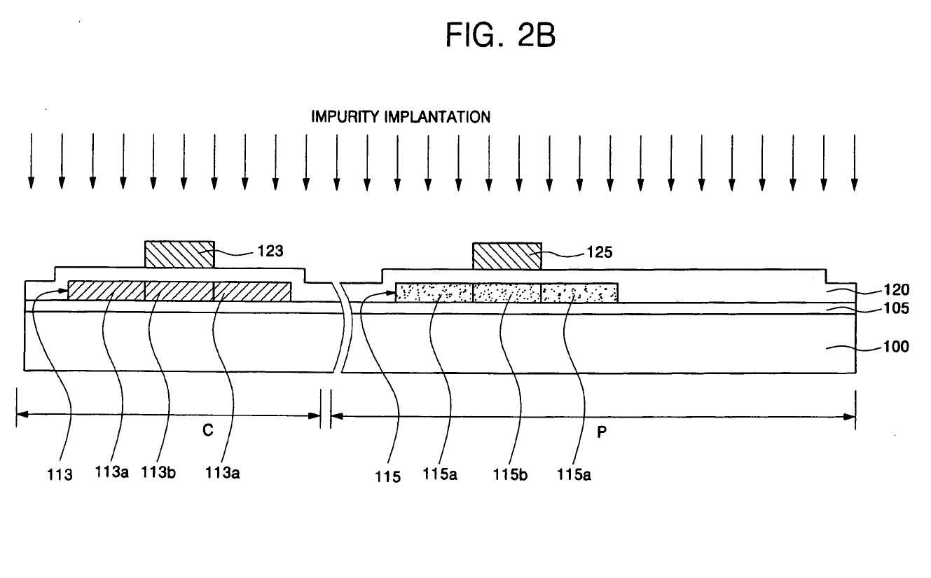

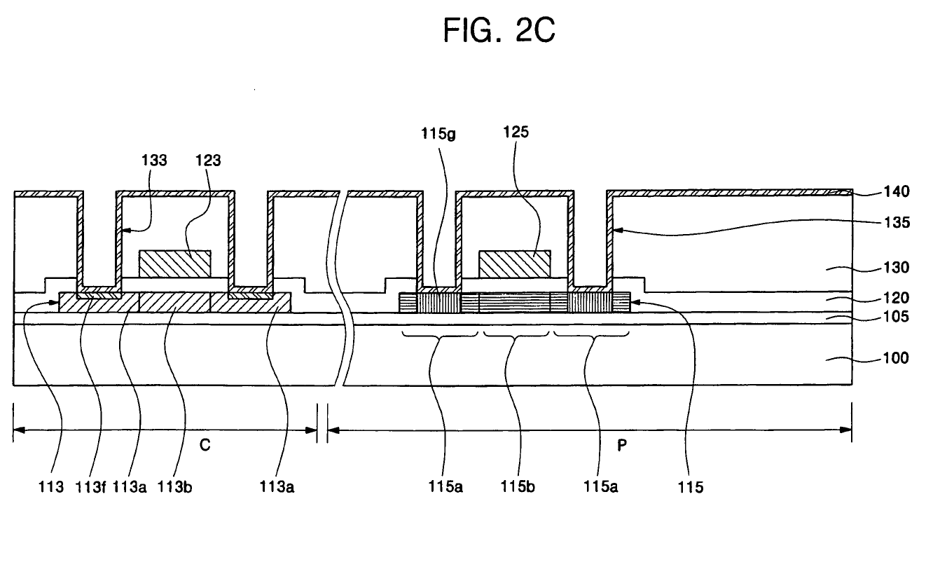

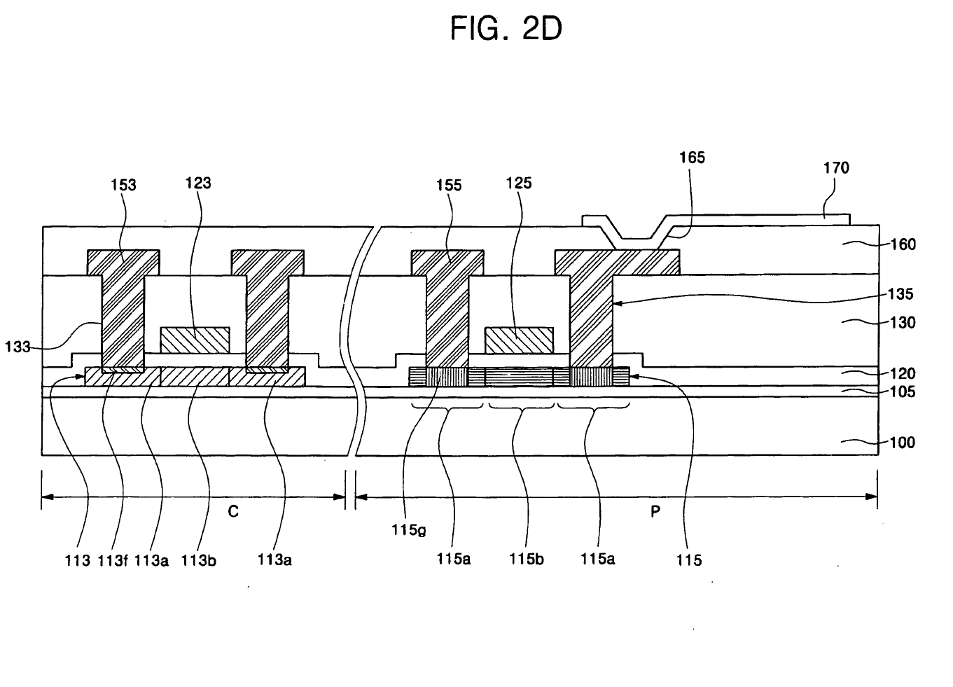

FIGS. 2A, 2B, 2C and 2D are cross-sectional views that illustrate a method for fabricating a flat panel display in accordance with a first embodiment of the present invention. The views are limited to the unit pixel of the pixel region P and some of the peripheral circuit region C shown in FIG. 1.

Referring to FIG. 2A, a substrate 100 having the peripheral circuit region C and the pixel region P is prepared. A buffer layer 105 is formed on the substrate 100. The buffer layer 105 acts to protect a semiconductor layer to be formed in a subsequent process from impurities emitted from the substrate 100. The buffer layer 105 is preferably formed of a silicon oxide layer.

An amorphous silicon layer 110 is deposited on the buffer layer 105. The amorphous silicon layer 110 may be deposited using a chemical vapor deposition (CVD) method. The amorphous silicon layer 110 is preferably deposited using a low pressure CVD (LPCVD) method. Next, the amorphous silicon layer 110 deposited on the substrate 100 is preferably dehydrogenated.

The amorphous silicon layer 110 of the peripheral circuit region C is selectively irradiated by laser passing through a mask 900. A shape of the laser beam is set when the laser passes through the mask 900. The region irradiated by the laser is melted to form a melted silicon region 110a, and the rest of the region maintains its solid state. After the laser irradiation, crystallization starts to occur from a boundary between the solid state silicon region and the melted silicon region 110a while the melted silicon region is being cooled. The substrate is finely moved to repeatedly perform the laser irradiation only for the amorphous silicon layer of the peripheral circuit region C, so that the amorphous silicon layer of the peripheral circuit region C becomes selectively crystallized. As a result, a polycrystalline silicon layer is formed on the peripheral circuit region C, and the pixel region P still has the amorphous silicon layer.

The method for crystallizing the amorphous silicon using the laser irradiated through the mask 900 to repeatedly perform melting and crystallization is referred to as a sequential lateral solidification (hereinafter, it will be herein referred to as SLS) method.

Referring to FIG. 2B, the polycrystalline silicon layer of the peripheral circuit region C and the amorphous silicon layer of the pixel region P are patterned to form a first semiconductor layer 113 in the peripheral circuit region C, and a second semiconductor layer 115 on the pixel region P.

Subsequently, a gate insulating layer 120 is formed over the entire surface of the substrate 100 including the semiconductor layers 113 and 115, and a gate conductive layer is deposited and patterned on the gate insulating layer 120 to thereby form a first gate electrode 123 on the gate insulating layer 120 of the peripheral circuit region C, and a second gate electrode 125 on the pixel region P, respectively. N or p type impurities are then implanted into the semiconductor layers 113 and 115 using the gate electrodes 123 and 125 as a mask, so that first source/drain regions 113a are formed in the first semiconductor layer 113 and second source/drain regions 115a are formed in the second semiconductor layer 115. At the same time, a first channel region 113b interposed between the first source/drain regions 113a, and a second channel region 115b interposed between the second source/drain regions 115a are defined.

Referring to FIG. 2C, an interlayer 130 is formed on the gate electrodes 123 and 125 and the semiconductor layers 113 and 115. A first source/drain contact hole 133 for exposing the first source/drain region 113a and a second source/drain contact hole 135 for exposing the second source/drain region 115a are formed in the interlayer 130. The first source/drain contact hole 133 is spaced apart from the first gate electrode 123, and the second source/drain contact hole 135 is spaced apart from the second gate electrode 125. A crystallization inducing metal layer 140 is deposited on the entire surface of the substrate 100 including the exposed source/drain regions 113a and 115a in the contact holes 133 and 135.

The crystallization inducing metal layer 140 may be formed of at least one metal selected from a group consisting of Ni, Pd, Ti, Ag, Au, Al, Sn, Sb, Cu, Co, Cr, Mo, Tr, Ru, Rh, and Cd. The crystallization inducing metal layer 140 may be particularly formed of Ni, because the Ni has less mismatch characteristics with silicon and may allow the crystallization to be performed at a low temperature. In addition, the crystallization inducing metal layer 140 is preferably formed to have a thickness of a few Å to 200 Å.

The substrate in which the crystallization inducing metal layer 140 is already formed is then subjected to thermal treatment in a furnace. By means of the thermal treatment, the source/drain regions 113a and 115a in contact with the crystallization inducing metal layer 140, react with metal that forms the crystallization inducing metal layer 140. In this case, crystallization is induced into the second semiconductor layer 115 by the metal in a region where the second semiconductor layer 115 and the crystallization induced metal layer 140 contact each other, so that a metal induced crystallization (hereinafter, it will be referred to as MIC) region 115g is formed. However, in the second semiconductor layer 115, a region not in contact with the crystallization inducing metal layer 140, namely, a region except the MIC region 115g is crystallized by a metal induced lateral crystallization (hereinafter, it will be referred to as MILC) method. As a result, the second channel region 115b not in contact with the crystallization inducing metal layer 140 of the second semiconductor layer 115 is crystallized by the MILC method. In addition, the MIC region 115g is formed to be spaced apart from the second channel region 115b. As a result, a boundary where the MIC region 115g and the region crystallized by the MILC method are in contact with each other may be positioned outside the second channel region 115b.

In the meantime, a metal silicide is formed in the first semiconductor layer 113 in contact with the crystallization inducing metal layer 140 because the first semiconductor layer 113 has already crystallized. A region where the metal silicide is formed is referred to as a metal silicide region 113f. In addition, the thermal treatment may activate impurities implanted in the semiconductor layers 113 and 115.

Referring to FIG. 2D, the remaining crystallization inducing metal layer 140 that has not reacted with the silicon in the semiconductor layers 113 and 115, is then removed to expose the metal silicide region 113f and the MIC region 115g within the contact holes 133 and 135. A source/drain conductive layer is deposited on the entire surface of the substrate including the contact holes 133 and 135, and the deposited layer is patterned. As a result, a first source/drain electrode 153 in contact with the metal silicide region 113f of the first semiconductor layer 113, and a second source/drain electrode 155 in contact with the MIC region 115g are formed.

The first semiconductor layer 113, the first gate electrode 123, and the first source/drain electrode 153 form a circuit thin film transistor, and the second semiconductor layer 115, the second gate electrode 125, and the second source/drain electrode 155 form a pixel thin film transistor. The first semiconductor layer 113 is one crystallized by the SLS method, and a region in contact with the first source/drain electrode 153 is the metal silicide region 113f in the first semiconductor layer 113. In the meantime, the second semiconductor layer 115 is one that has a channel region crystallized by the MILC method, and a region below the second source/drain electrode 155 is the MIC region 115g in the second semiconductor layer 115.

Subsequently, a passivation layer 160 is deposited on the substrate 100 where the source/drain electrodes 153 and 155 are already formed, and a via hole 165 is formed within the passivation layer 160 to expose any one of the second source/drain electrodes 155. A pixel electrode material is deposited on the entire surface of the substrate, including the via hole 165, and patterned to form a pixel electrode 170. By way of example, the pixel electrode material may be ITO (Indium Tin Oxide) or IZO (Indium Zinc Oxide).

A pixel defining layer (not shown) is then formed on the entire surface of the substrate including the pixel electrode 170 and patterned to expose a predetermined region of the pixel electrode 170, and an organic functional layer (not shown) including an emission layer is formed on the exposed pixel electrode 170. An opposite electrode (not shown) is then formed on the organic functional layer so that an organic light-emitting display devide may be fabricated. Alternatively, an alignment layer (not shown) may be formed on the pixel electrode 170 to fabricate a lower substrate of a liquid crystal device.

In one embodiment, the first semiconductor layer 113 crystallized by the SLS method has superior crystallization properties enough to represent a single crystal level. The crystallization properties having the single crystal level may enhance the electron mobility characteristic of the circuit thin film transistor. In the meantime, the second semiconductor layer 115 has a channel region crystallized by the MILC method. Therefore, the pixel thin film transistor having the second semiconductor layer 115 does not have as high electron mobility as that of the circuit thin film transistor having the first semiconductor layer 113 crystallized by the SLS method; however, the pixel thin film transistor may have uniform electrical characteristics as compared to that of the circuit thin film transistor. And also, it is more productive to selectively crystallize the second semiconductor layer 115 by MILC method than to crystallize the second semiconductor layer 115 by SLS as the first semiconductor layer 113 was crystallized. In detail, the SLS method requires the laser to be repeatedly irradiated while the substrate is finely moved, so that it takes a long time to crystallize all the silicon layers and requires high priced laser equipment, which is not preferable in terms of productivity.

As such, in one embodiment, the first semiconductor layer 113 of the peripheral circuit region C is selectively crystallized by the SLS method, and the second semiconductor layer 115 of the pixel region P is selectively crystallized by the MILC method, so that a flat panel display may be obtained, which simultaneously includes a pixel thin film transistor having the uniform electrical characteristics over the entire pixel region, and a circuit thin film transistor having the electron mobility higher than that of the pixel thin film transistor.

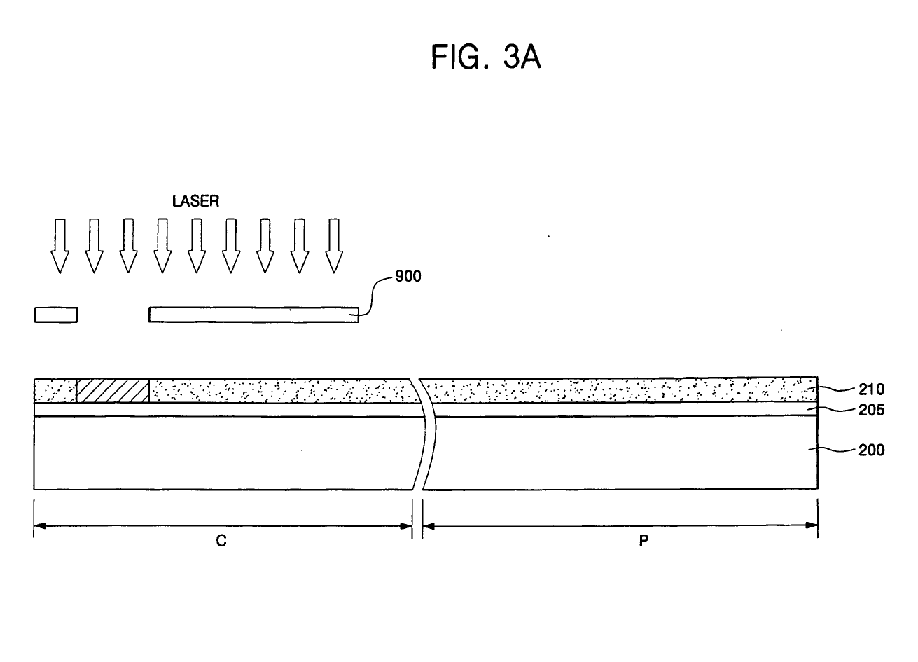

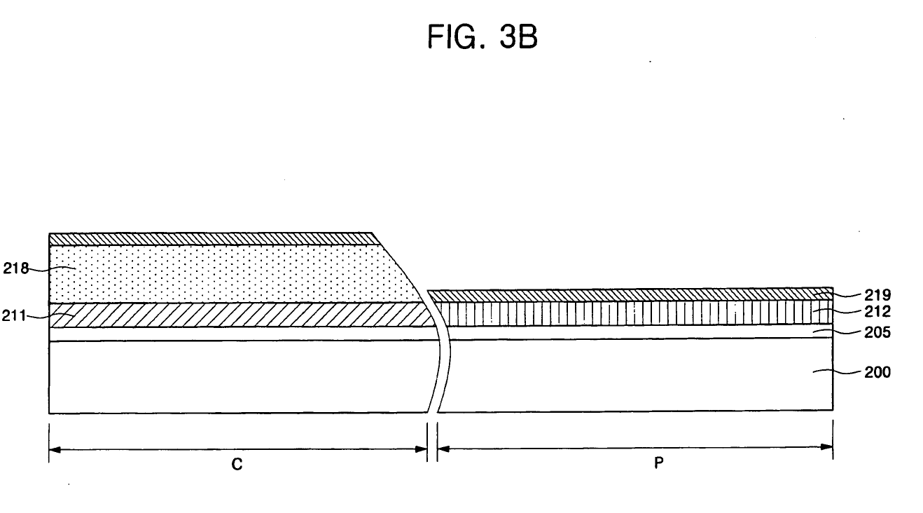

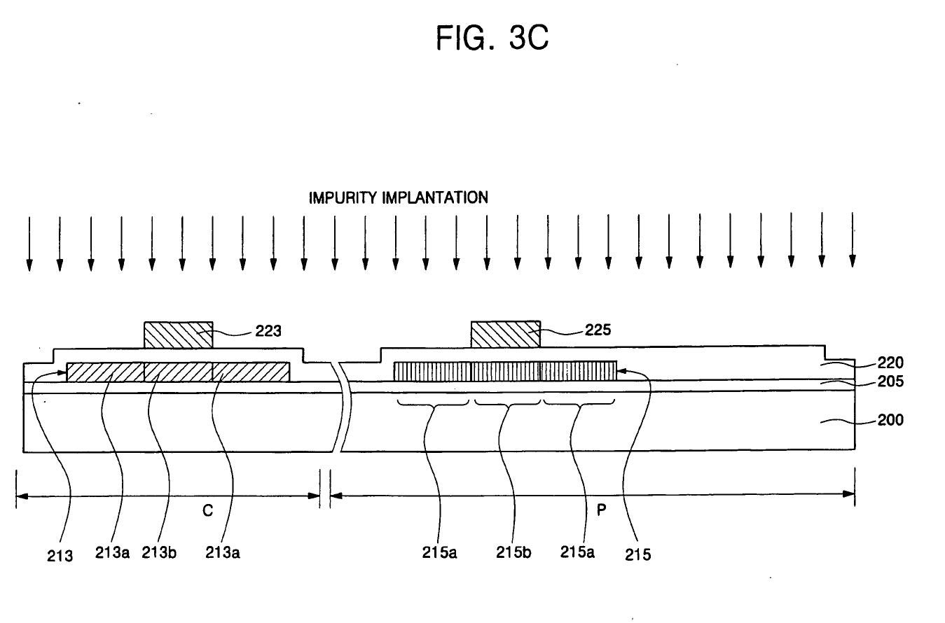

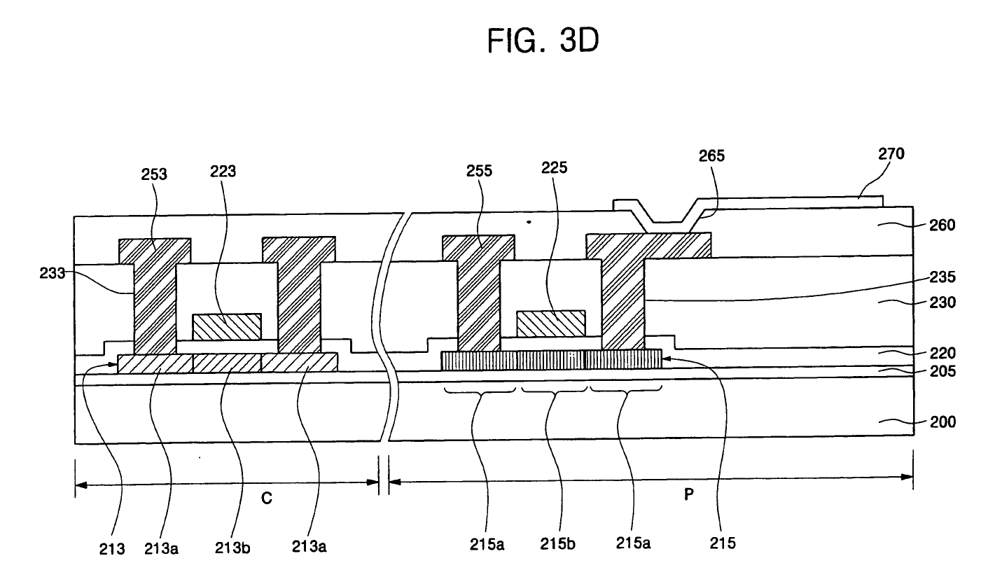

FIGS. 3A, 3B, 3C and 3D are cross-sectional views for explaining a method for fabricating a flat panel display in accordance with a second embodiment of the present invention. The views are limited to a unit pixel of the pixel region P and some of the peripheral circuit region C as shown in FIG. 1.

Referring to FIG. 3A, there is provided a substrate 200 including the peripheral circuit region C and a pixel region P. A buffer layer 205 is formed on the substrate 200, and an amorphous silicon layer 210 is deposited on the buffer layer 205. The amorphous silicon layer 210 deposited on the substrate 200 is preferably dehydrogenated. A description for the buffer layer 205 and the amorphous silicon layer 210 is the substantially same as the buffer layer 105 and the amorphous silicon layer 110 in the first embodiment.

The amorphous silicon layer 210 of the peripheral circuit region C is selectively irradiated by laser that passes through a mask 900. The laser irradiation is repeatedly performed while the substrate 200 is finely moved, so that the amorphous silicon of the peripheral circuit region C is crystallized by the SLS method. As a result, a polycrystalline silicon layer is formed on the peripheral circuit region C. In this case, the amorphous silicon layer 210 is still present on the pixel region P. A description for the SLS method is the same as the first embodiment.

Referring to FIG. 3B, a photoresist pattern 218 is formed on the polycrystalline silicon layer 211 of the peripheral circuit region C to expose the amorphous silicon layer (210 of FIG. 3A) of the pixel region P. A crystallization inducing metal layer 219 is formed on the exposed amorphous silicon layer of the pixel region P.

The crystallization inducing metal layer 219 may be formed of at least one metal selected from a group consisting of Ni, Pd, Ti, Ag, Au, Al, Sn, Sb, Cu, Co, Cr, Mo, Tr, Ru, Rh, and Cd. The crystallization inducing metal layer 219 may be particularly formed of Ni, because Ni has less mismatch characteristics with silicon and may allow the crystallization to be performed at a low temperature. In addition, the crystallization inducing metal layer 219 is preferably formed to have a thickness of a few Å to 200 Å.

The substrate in which the crystallization inducing metal layer 219 is already formed is then subjected to thermal treatment in a furnace. During this time, the amorphous silicon layer of the pixel region P in contact with the crystallization inducing metal layer 219 reacts with metal that forms the crystallization inducing metal layer 219. Thus, the amorphous silicon layer of the pixel region P is crystallized by the MIC method to form a polycrystalline silicon layer 212.

Referring to FIG. 3C, remaining crystallization inducing metal layer (219 of FIG. 3B) that has not reacted with the silicon is then removed to expose the polycrystalline silicon layer (212 of FIG. 3B) of the pixel region P. The polycrystalline silicon layer (211 of FIG. 3B) of the peripheral circuit region C and the polycrystalline silicon layer (212 of FIG. 3B) of the pixel region P, which are crystallized by methods different from each other, are then patterned to form a first semiconductor layer 213 and a second semiconductor layer 215 in the peripheral circuit region C and the pixel region P, respectively.

Subsequently, a gate insulating layer 220 is formed over the entire surface of the substrate 200 including the semiconductor layers 213 and 215, and a gate conductive layer is deposited and patterned on the gate insulating layer 220 to thereby form a first gate electrode 223 and a second gate electrode 225 on the gate insulating layer 220 of the peripheral circuit region C and the pixel region P, respectively. N or P type impurities are implanted into the semiconductor layers 213 and 215 using the gate electrodes 223 and 225 as a mask, so that first source/drain regions 213a are formed in the first semiconductor layer 213 and second source/drain regions 215a are formed in the second semiconductor layer 215, respectively. At the same time, a first channel region 213b interposed between the first source/drain regions 213a, and a second channel region 215b interposed between the second source/drain regions 215a are defined.

Referring to FIG. 3D, an interlayer 230 is formed on the gate electrodes 223 and 225 and the semiconductor layers 213 and 215. A first source/drain contact hole 233 for exposing the first source/drain region 213a and a second source/drain contact hole 235 for exposing the second source/drain region 215a are formed in the interlayer 230.

A source/drain conductive layer is deposited on the entire surface of the substrate including the contact holes 233 and 235, and then the deposited layer is patterned. As a result, a first source/drain electrode 253 in contact with the first semiconductor layer 213, and a second source/drain electrode 255 in contact with the second semiconductor layer 215 are formed.

The first semiconductor layer 213, the first gate electrode 223, and the first source/drain electrode 253 form a circuit thin film transistor, and the second semiconductor layer 215, the second gate electrode 225, and the second source/drain electrode 255 form a pixel thin film transistor. The first semiconductor layer 213 is one crystallized by the SLS method, and the second semiconductor layer 215 is one that has the channel region 215b crystallized by the MIC method.

Then, a passivation layer 260 is deposited on the substrate 200 where the source/drain electrodes 253 and 255 are already formed, and a via hole 265 is formed within the passivation layer 260 to expose any one of the second source/drain electrodes 255. A pixel electrode material is deposited on the entire surface of the substrate including the via hole 265 and patterned to form a pixel electrode 270. By way of example, the pixel electrode material may be ITO or IZO.

The first semiconductor layer 213 crystallized by the SLS method has superior crystallization properties enough to represent a single crystal level. The crystallization properties having the single crystal level may enhance the electron mobility characteristic of the circuit thin film transistor. In the meantime, the second semiconductor layer 215 has the channel region crystallized by the MIC. Therefore, the pixel thin film transistor having the second semiconductor layer 215 does not have as high electron mobility as that of the circuit thin film transistor having the first semiconductor layer 213 crystallized by the SLS method; however, the pixel thin film transistor may have uniform electrical characteristics as compared to that of the circuit thin film transistor. And also, it is more productive to selectively crystallize the second semiconductor layer 215 by MIC method than crystallize the second semiconductor layer 215 by SLS as the first semiconductor layer 213.

As such, in the present embodiment, the first semiconductor layer 213 of the peripheral circuit region C is selectively crystallized by the SLS method, and the second semiconductor layer 215 of the pixel region P is selectively crystallized by the MIC method, so that a flat panel display may be obtained, which simultaneously includes a pixel thin film transistor having the uniform electrical characteristic over the entire pixel region P, and a circuit thin film transistor having the electron mobility higher than that of the pixel thin film transistor.

In accordance with the embodiments of the above-mentioned invention, the first semiconductor layer of the circuit region and the first semiconductor layer of the pixel region are formed by crystallization methods different from each other, so that a flat panel display may be obtained, which simultaneously includes a pixel thin film transistor having the uniform electrical characteristics over the entire pixel region, and a circuit thin film transistor having the electron mobility higher than that of the pixel thin film transistor.

While the present invention has been described with reference to a particular embodiment, it is understood that the disclosure has been made for purpose of illustrating the invention by way of examples and is not limited to limit the scope of the invention. And one skilled in the art can make, amend, and change the present invention without departing from the scope and spirit of the invention.

1. A flat panel display, comprising:
a pixel region having a plurality of unit pixels and a peripheral circuit region arranged in a periphery of the pixel region, the peripheral circuit region having a driving circuit for driving the plurality of unit pixels;
at least one circuit thin film transistor positioned in the peripheral circuit region and including a first semiconductor layer crystallized by a sequential lateral solidification method; and
at least one pixel thin film transistor positioned in the pixel region and including a second semiconductor layer having a channel region crystallized by one of a metal induced crystallization method and a metal induced lateral crystallization method.

2. The flat panel display of claim 1, wherein the second semiconductor layer has a channel region crystallized by the metal induced lateral crystallization method.

3. The flat panel display of claim 2, wherein the second semiconductor layer has a region that is spaced from the channel region and crystallized by the metal induced crystallization method.

4. The flat panel display of claim 2, wherein the pixel thin film transistor further includes:
a second gate electrode positioned on the second semiconductor layer; and
a second source/drain electrode that is spaced from the second gate electrode and in contact with the second semiconductor layer,
wherein the second semiconductor layer has a region below the second source/drain electrode crystallized by the metal induced crystallization method.

5. The flat panel display as claimed in claim 2, wherein the circuit thin film transistor further includes:
a first gate electrode positioned on the first semiconductor layer; and
a first source/drain electrode that is spaced from the first gate electrode and in contact with the first semiconductor layer,
wherein the first semiconductor layer has a metal silicide layer formed in a region in contact with the first source/drain electrode.

6. The flat panel display as claimed in claim 1, wherein the flat panel display is one of a liquid crystal display or an organic light emitting display.

7. A method for fabricating a flat panel display, comprising:
preparing a substrate to include a pixel region and a peripheral circuit region arranged in a periphery of the pixel region;
depositing an amorphous silicon layer on the substrate;
selectively crystallizing the amorphous silicon layer of the peripheral circuit region using a sequential lateral solidification method to form a polycrystalline silicon layer; and
selectively crystallizing the amorphous silicon layer of the pixel region using one of a metal induced lateral crystallization method or a metal induced crystallization method.

8. The method as claimed in claim 7, wherein the selectively crystallizing the amorphous silicon layer of the pixel region includes further:
patterning the polycrystalline silicon layer of the peripheral circuit region and the amorphous silicon layer of the pixel region to simultaneously form a first semiconductor layer in the peripheral circuit region and a second semiconductor layer in the pixel region; and
selectively crystallizing the second semiconductor layer of the pixel region by means of the metal induced lateral crystallization method.

9. The flat panel display as claimed in claim 8, wherein a metal silicide layer is formed in the first semiconductor layer of the peripheral circuit region while the second semiconductor layer of the pixel region is selectively crystallized by the metal induced lateral crystallization method.

10. The flat panel display as claimed in claim 9, wherein the selectively crystallizing the second semiconductor layer of the pixel region by means of the metal induced lateral crystallization method while forming the metal silicide in the first semiconductor layer of the peripheral circuit region further includes:
forming a first gate electrode on the first semiconductor layer of the peripheral circuit region and a second gate electrode on the second semiconductor layer of the pixel region, respectively;
forming an interlayer on the gate electrodes and the semiconductor layers;
forming a first source/drain contact hole for exposing a portion of the first semiconductor layer and a second source/drain contact hole for exposing a portion of the second semiconductor layer within the interlayer;
depositing a crystallization inducing metal layer on the semiconductor layers exposed within the source/drain contact holes; and
performing thermal treatment on the substrate where the crystallization inducing metal layer is deposited.

11. The flat panel display as claimed in claim 10, wherein the forming the crystallization inducing metal layer is performed using at least one metal selected from a group consisting of Ni, Pd, Ti, Ag, Au, Al, Sn, Sb, Cu, Co, Cr, Mo, Tr, Ru, Rh, and Cd.

12. The flat panel display as claimed in claim 11, wherein the forming the crystallization inducing metal layer is performed using Ni.

13. The flat panel display as claimed in claim 7, wherein the selectively crystallizing the amorphous silicon layer of the pixel region using the metal induced crystallization method further includes:
forming a photoresist pattern for covering the polycrystalline silicon layer of the peripheral circuit region and for exposing the amorphous silicon layer of the pixel region;
forming a crystallization inducing metal layer on the exposed amorphous silicon layer; and
performing thermal treatment on the substrate where the crystallization inducing metal layer is formed.

14. The flat panel display as claimed in claim 13, wherein the forming the crystallization inducing metal layer is performed using at least one metal selected from a group consisting of Ni, Pd, Ti, Ag, Au, Al, Sn, Sb, Cu, Co, Cr, Mo, Tr, Ru, Rh, and Cd.

15. The flat panel display as claimed in claim 14, wherein the forming the crystallization inducing metal layer is performed using Ni.
